(19) United States
(12) Patent Application Publication
(10) Pub. No.: US 2026/0136785 A1
(43) Pub. Date: May 14, 2026

(54) DISPLAY APPARATUS

(71) Applicant: LG DISPLAY CO., LTD., Seoul (KR)

(72) Inventor: Joonyoung Heo, Seoul (KR)

(73) Assignee: LG DISPLAY CO., LTD., Seoul (KR)

(21) Appl. No.: 19/289,754

(22) Filed: Aug. 4, 2025

(30) Foreign Application Priority Data
Nov. 8, 2024 (KR) 10-2024-0158519

(51) Int. Cl. H10K 59/131; H10K 59/121

(52) U.S. Cl. CPC H10K 59/131; H10K 59/121

(57) ABSTRACT

A display apparatus can include a substrate having a display area and a non-display area, at least two emission areas disposed on the display area and constituting one sub-pixel, a trench portion disposed at least outside of each emission area, at least two contact areas disposed to be spaced apart from the respective emission areas, a first electrode disposed in each emission area, a contact wiring portion disposed in each contact area, an emission layer disposed on the first electrode, and a second electrode disposed on the emission layer and separated in the two emission areas by the trench portion. The separated portions of the second electrode can be electrically connected to the contact wiring portions, respectively.

### CROSS-REFERENCE TO RELATED APPLICATION

The present application claims priority to Korean Patent Application No. 10-2024-0158519, filed in the Republic of Korea on Nov. 8, 2024, the entire contents of which is hereby expressly incorporated by reference into the present application.

### BACKGROUND

### Technical Field

This disclosure relates to a display apparatus.

### Discussion of the Related Art

Display apparatuses are applied to various electronic devices such as TVs, smart phones, laptops, and tablets. To this end, a range of researches have been conducted to develop display apparatuses that are thinner, lighter, and have lower power consumption.

Among various display apparatuses that display information as images, an organic light-emitting display (OLED) apparatus is a self-luminous element that emits light not through an external light source but by itself. The organic light-emitting display apparatuses have advantages such as fast response speed, high luminous efficiency, high brightness, large viewing angle, high contrast ratio, and excellent color reproducibility.

As the demand for high-resolution display apparatuses has increased recently, the scope of application of the organic light-emitting display apparatus is expanding.

### SUMMARY OF THE DISCLOSURE

During the manufacturing process of an organic light-emitting display apparatus, there can occur a phenomenon in which the brightness of the display area decreases. One of the causes of this phenomenon in which the brightness in the display area is reduced can be that dark spots occur locally in the sub-pixels arranged on the display area, thereby increasing the area where light is not emitted.

The dark spots can be caused by defective sub-pixels that fail to emit light. Defective sub-pixels can be caused, for example, by an impact from the outside of the display apparatus, an unnecessary reaction incurred by gas or the like generated inside the display apparatus, or damage to the emission layer containing organic materials induced by moisture or oxygen.

Even though dark spots occur in some portions of the display area, they are likely to reduce the quality of the image provided across the entire display area, thus reducing user immersion and degrading the reliability of the display apparatus.

To overcome the above-described drawbacks, the inventor of the present disclosure has invented, through various experiments, a display apparatus capable of driving a defective sub-pixel as a normal sub-pixel.

An object to be accomplished according to an embodiment of the present disclosure is to provide a display apparatus capable of driving a defective sub-pixel as a normal sub-pixel.

Additionally, an object to be accomplished according to an embodiment of the present disclosure is to provide a display apparatus whose yield can be improved by easily removing dark spots from defective sub-pixels without using a laser process.

The objects to be accomplished according to an embodiment of the present disclosure are not limited to the ones described above, and other objects and advantages of the present invention which are not mentioned can be understood from the following description, and will be more clearly understood from the embodiments of the present invention. Furthermore, it will be readily appreciated that the objects and advantages of the present disclosure can be realized by the means presented in the claims, and combinations thereof.

A display apparatus according to embodiments of the present disclosure can include a substrate including a display area and a non-display area, at least two emission areas disposed on the display area and constituting one sub-pixel, a trench portion disposed at least outside each emission area, at least two contact areas disposed to be spaced apart from the respective emission areas, a first electrode disposed in each emission area, a contact wiring portion disposed in each contact area, an emission layer disposed on the first electrode, and a second electrode disposed on the emission layer and separated in the two emission areas by the trench portion. The separated portions of the second electrode can be electrically connected to the contact wiring portions, respectively.

According to an embodiment of the present disclosure, a sub-pixel which emits light of one color can include a pair of sub-pixels. With this configuration, even if a defect occurs in one sub-pixel of the pair of sub-pixels, the remaining sub-pixel thereof can emit light, so that the corresponding sub-pixel can be used as a normal sub-pixel.

According to aspects of the present disclosure, the pair of sub-pixels emitting light of one color can be supplied separately with power voltages by disposing cathode electrodes and cathode contacts separated from each other by a trench, a protrusion pattern, and the like, so that one cathode electrode is connected to each sub-pixel.

Thereby, even if one of a pair of sub-pixels emitting light of one color has a defect and does not light up, normal operation thereof can be achieved by supplying power voltage to the other sub-pixel. Therefore, the corresponding sub-pixel can operate normally.

Consequently, according to the embodiments of the present disclosure, a repair process through laser cutting or the like can be omitted, thereby optimizing the process steps and improving the yield of the display apparatus. Additionally, even if a defect occurs in some of the sub-pixels, the corresponding sub-pixel can operate normally, thereby improving the reliability of the display apparatus.

Therefore, according to aspects of the present disclosure, it is possible to prevent or minimize a defect such as reduction in brightness caused by a dark spot in which a sub-pixel does not emit light. Consequently, the display apparatus can realize high brightness, so that it can be driven with low power, thereby reducing power consumption.

Further, according to aspects of the present disclosure, it is possible to improve the reliability of the product by preventing dark spot defects from occurring in the display area, thereby increasing the user's immersion into the screen.

The present disclosure can have other effects besides the aforementioned ones, which are clearly recognizable to a person skilled in the art from the description below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to an embodiment of the present disclosure;

FIG. 2 is a plan view showing an example of pixels disposed in area I of FIG. 1;

FIG. 3 is a cross-sectional view taken along line II-II' in FIG. 2;

FIG. 4 is a plan view showing one sub-pixel disposed in area III of FIG. 2;

FIG. 5 is a cross-sectional view taken along line IV-IV' in FIG. 4;

FIGS. 6-13 are views showing a method for manufacturing a display apparatus according to an embodiment of the present disclosure;

FIG. 14 is a view according to a modified example of an embodiment of the present disclosure;

FIG. 15 is a view according to another embodiment of the present disclosure;

FIGS. 16-21 are views showing a method for manufacturing a display apparatus according to another embodiment of the present disclosure; and

FIGS. 22 and 23 are equivalent circuit diagrams of one sub-pixel of a display apparatus according to embodiments of the present disclosure.

### DETAILED DESCRIPTION OF THE EMBODIMENTS

Advantages and features of the present disclosure, and a method of achieving the advantages and features will become apparent when referring to the following embodiments described later in detail together with the accompanying drawings. However, the present disclosure is not limited to the embodiments as disclosed below, but can be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology can unnecessarily obscure the gist of the present disclosure, the detailed description thereof will be omitted. When the terms "comprise", "include", "have", "be configured with", "be comprised of", and the like are used in the present disclosure, the presence or addition of other element can be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “next to”, and the like, one or more other elements can be interposed between the two elements unless “just”, “directly”, or "close" is used.

In describing a temporal relationship, for example, when the temporal order is described as “after”, “subsequent”, “next”, “before”, and the like, the case which is not continuous can also be included unless the term “just” or “directly” is used.

It will be understood that, although the terms “first”, “second”, etc. can be used herein to describe various elements, these elements should not be limited by these terms. These terms are merely used to distinguish one element from another element and may not define order or sequence. So, a first element referred to in the following description can represent a second element, without departing from the scope of the technical idea of the present disclosure. Further,

The individual features of the various embodiments of the present disclosure can be coupled or combined with each other in part or in whole to be interconnected and operated in a variety of technical ways, and each embodiment can be implemented independently of each other or implemented together in an associative relationship.

Hereinafter, a display apparatus according to each embodiment of this disclosure will be described with reference to the accompanying drawings. All the components of each display apparatus/device according to all embodiments of the present disclosure are operatively coupled and configured.

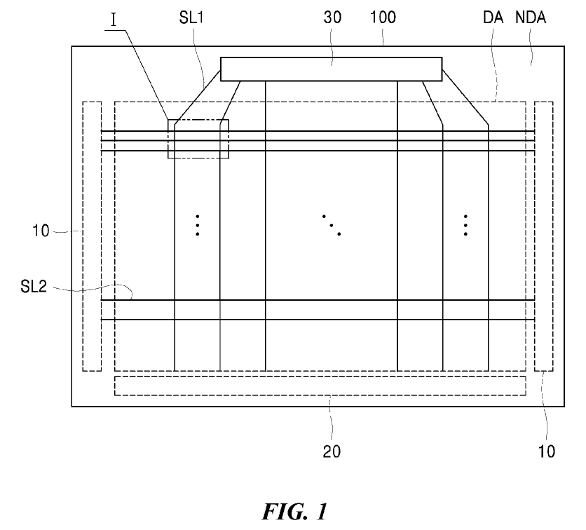

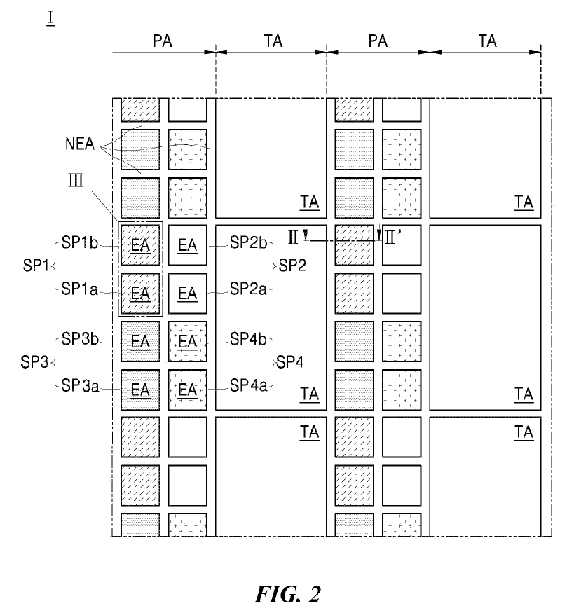

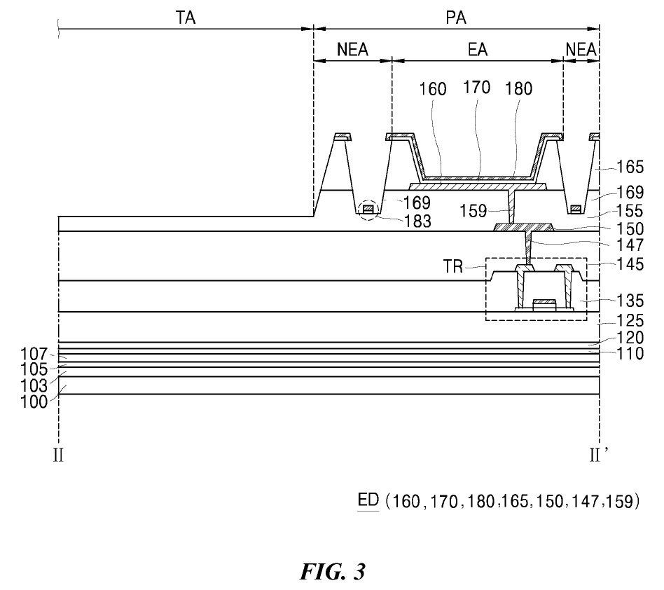

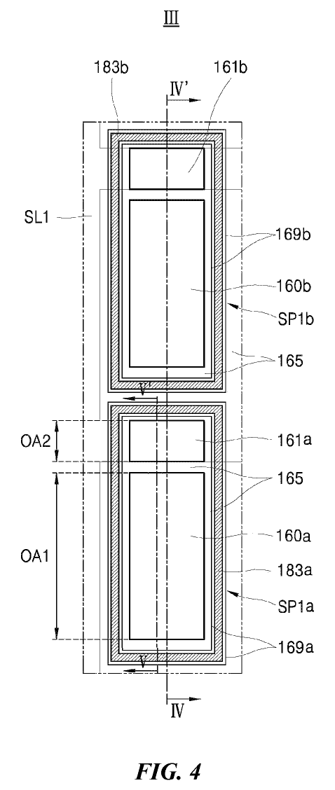

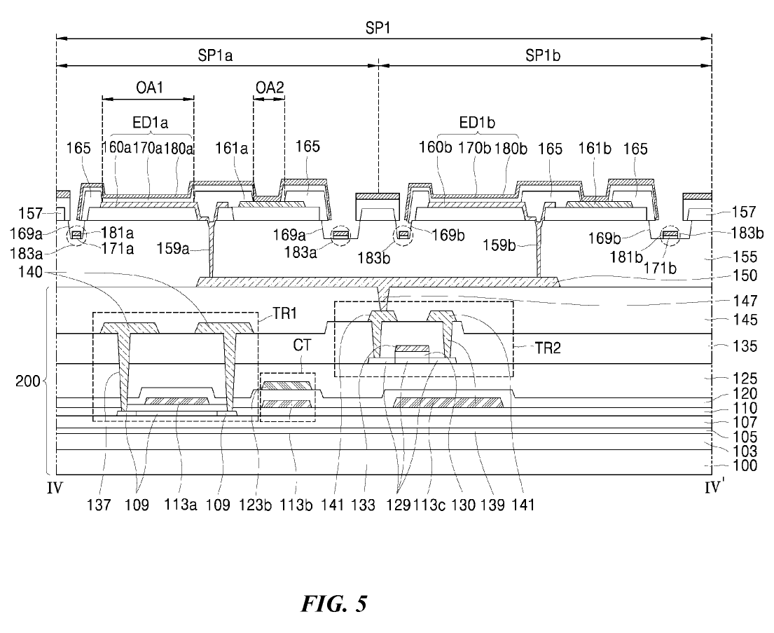

FIG. 1 is a plan view of a display apparatus according to an embodiment of the present disclosure. FIG. 2 is a plan view showing an example of pixels disposed in area I of FIG. 1. FIG. 3 is a cross-sectional view taken along line II-II' in FIG. 2. FIG. 4 is a plan view showing one sub-pixel disposed in area III of FIG. 2. FIG. 5 is a cross-sectional view taken along line IV-IV' in FIG. 4.

Referring to FIGS. 1 and 2, a display apparatus according to embodiments of the present disclosure can include a substrate 100 having a display area DA and a non-display area NDA located outside the display area DA.

The display area DA can be an area where an image is displayed, and the non-display area NDA can be an area where no image is displayed. The non-display area NDA can be located in the peripheral area (or border area) of the substrate 100; however, this is not exhaustive. For example, the remaining portion of the display area DA except an emission area from which light is emitted to the outside can be referred to as the non-display area DNA.

A display apparatus according to an embodiment of the present disclosure can be a transparent display apparatus that, while displaying an image, transmits light so that a background or an object disposed in the rear side of the display apparatus can be visually perceived by a user.

In the display area DA a plurality of pixels can be disposed. An image can be displayed in the display area DA through the plurality of pixels. In the non-display area NDA various wirings and circuits can be disposed for driving the plurality of pixels in the display area DA. For example, the non-display area NDA can accommodate a gate driver 10, a data driver 20, and a power supply portion 30. The non-display area NDA can also include a timing controller.

The gate driver 10 can be configured in a GIP (Gate driver in panel) manner on one edge or opposite edges of the substrate 100. The gate driver 10 can generate gate signals. The gate signals can be provided to pixels through scan lines.

The data driver 20 can generate data signals. The data signals can be provided to pixels in the display area DA through a plurality of data lines.

The power supply portion 30 can generate a high-potential power voltage (EVDD) and a low-potential power voltage (EVSS) to be provided to the display area DA. The power supply portion 30 can provide the generated high-potential power voltage (EVDD) and low-potential power voltage (EVSS) to pixels through signal lines.

The display area DA can include a plurality of first signal lines SL1 and a plurality of second signal lines SL2. The plurality of first signal lines SL1 can extend in a first direction of the substrate 100, and the plurality of second signal lines SL2 can extend in a second direction of the substrate 100. The first direction can be the Y-axis direction, and the second direction can be the X-axis direction intersecting with the first direction; however, this is not exhaustive.

The plurality of first signal lines SL1 can include at least one of a common power line, a data line, a pixel power line, and a reference power line. The plurality of second signal lines SL2 can include at least one of a scan line and a cathode contact wiring.

The display area DA can include a plurality of transmission areas TA and a plurality of pixel areas PA. The transmission areas TA and the pixel areas PA can be disposed alternately in the X-axis direction, which is the second direction of the substrate 100. The plurality of transmission areas TA can be disposed to be spaced apart from each other in the Y-axis direction, which is the first direction. However, this is not exhaustive.

The transmission area TA can transmit light to allow the back surface of the display apparatus to be perceived. For this purpose, the transmission area TA can be an area where no opaque or reflective material is disposed. Thereby, the transmission area TA can be an area with high light transmittance. The pixel area PA can be an area that transmits little external light. The pixel area PA can be an area in which a plurality of sub-pixels SP1, SP2, SP3, SP4 are disposed. Besides, the pixel area PA can be an area where light-emitting elements are disposed corresponding to the respective sub-pixels SP1, SP2, SP3, SP4.

The pixel area PA can be disposed between neighboring transmission areas TA, and have a plurality of signal lines disposed therein for driving the plurality of sub-pixels SP1, SP2, SP3, SP4. The transmission area TA may not overlap with the plurality of signal lines disposed in the pixel area PA. In addition, the transmission area TA may not overlap with the light-emitting elements disposed in the plurality of sub-pixels SP1, SP2, SP3, SP4.

Each of the plurality of sub-pixels SP1, SP2, SP3, SP4 disposed on the pixel area PA includes an area that emits light corresponding to one color. Three or four or more sub-pixels of the plurality of sub-pixels SP1, SP2, SP3, SP4, which are adjacent to each other and correspond to different colors, can form one pixel area that emits light of various colors.

By the combination of the lights emitted from two or more sub-pixels SP1, SP2, SP3, SP4 implementing one pixel area and neighboring each other, the pixel area can display various colors, thereby emitting an image to the display area DA. For example, one pixel disposed in a pixel area can include a first sub-pixel SP1, a second sub-pixel SP2, a third sub-pixel SP3, and a fourth sub-pixel SP4. An emission area EA can be disposed corresponding to each sub-pixel SP1, SP2, SP3, SP4.

The emission areas EA disposed in the respective sub-pixels SP1, SP2, SP3, SP4 can emit light of different colors. For example, the first sub-pixel SP1 can have a first emission area EA located therein and emitting a light of a first color; the second sub-pixel SP2 can have a second emission area EA located therein and emitting a light of a second color; the third sub-pixel SP3 can have a third emission area EA located therein and emitting a light of a third color; and the fourth sub-pixel SP4 can have a fourth emission area EA located therein and emitting a light of a fourth color. For example, the light of the first color can be green light; the light of the second color can be white light; the light of the third color can be blue light; and the light of the fourth color can be red light. However, the embodiments of the present disclosure are not limited to this. Further, the arrangement order and arrangement direction of the sub-pixels SP1, SP2, SP3, SP4 can be changed in various ways.

Each of the plurality of pixels can include one or more first sub-pixels SP1, one or more second sub-pixels SP2, one or more third sub-pixels SP3, and one or more fourth sub-pixels SP4. For example, one pixel can include a pair of first sub-pixels SP1, a pair of second sub-pixels SP2, a pair of third sub-pixels SP3, and a pair of fourth sub-pixels SP4. The pair of first sub-pixels SP1 can be configured with a first-first sub-pixel SP1a and a first-second sub-pixel SP1b. The pair of second sub-pixels SP2 can be configured with a second-first sub-pixel SP2a and a second-second sub-pixel SP2b. The pair of third sub-pixels SP3 can be configured with a third-first sub-pixel SP3a and a third-second sub-pixel SP3b. The pair of fourth sub-pixels SP2can be configured with a fourth-first sub-pixel SP4a and a fourth-second sub-pixel SP4b.

Accordingly, one unit pixel can include the first-first sub-pixel SP1a, the first-second sub-pixel SP1b, the second-first sub-pixel SP2a, the second-second sub-pixel SP2b, the third-first sub-pixel SP3a, the third-second sub-pixel SP3b, the fourth-first sub-pixel SP4a, and the fourth-second sub-pixel SP4b. However, the embodiments of the present disclosure are not limited to this.

The plurality of sub-pixels constituting one unit pixel can be arranged in various ways. For example, in one unit pixel, the pair of first sub-pixels SP1 can be disposed in the same column; the pair of second sub-pixels SP2 can be disposed in the same column; the pair of third sub-pixels SP3 can be disposed in the same column; and the pair of fourth sub-pixels SP4 can be disposed in the same column. The first sub-pixel SP1 and the second sub-pixel SP2 can be disposed in the same row, and the third sub-pixel SP3 and the fourth sub-pixel SP4 can be disposed in the same row. The number and arrangement of the plurality of sub-pixels constituting one unit pixel are given only as an example, and the embodiments of the present disclosure are not limited thereto.

Any one of the pair of sub-pixels can be a main sub-pixel, and the other sub-pixel can be a redundancy sub-pixel. The redundancy sub-pixel can be a sub-pixel that can be repaired to operate as a normal sub-pixel in case of a defect on the main sub-pixel. If a defect occurs in the main sub-pixel, the redundancy sub-pixel can emit light to be used as a normal sub-pixel. Therefore, by disposing the main sub-pixel and the redundancy sub-pixel together in one sub-pixel, it is possible to prevent the display quality degradation which would otherwise be caused by the sub-pixel defect.

For example, among the sub-pixels disposed in one unit pixel, the first-first sub-pixel SP1a, the second-first sub-pixel SP2a, the third-first sub-pixel SP3a, and the fourth-first sub-pixel SP4a can be used as main sub-pixels, while the first-second sub-pixel SP1b, the second-second sub-pixel SP2b, the third-second sub-pixel SP3b, and the fourth-second sub-pixel SP4b can be used as redundancy sub-pixels. This will be described later in further detail.

Referring to FIGS. 2 and 3, the substrate 100 according to an embodiment of the present disclosure can include a transmission area TA and a pixel area PA. The pixel area PA can include an emission area EA and a non-emission area NEA. In the pixel area PA a light-emitting element ED and circuit elements for driving the light-emitting element ED can be disposed. For example, in the pixel area PA there can be included a plurality of transistors TR, a light-emitting element ED having an anode electrode 160, an emission layer 170, and a cathode electrode 180, a bank 165, a connection electrode 150 and via electrodes 147, 159 electrically connecting the plurality of transistors TR with the light-emitting element ED, and layers 103, 105, 107, 110, 120, 125, 135, 145, 155 which are insulating. The pixel area PA can further include a structure 183 and a trench portion 169 disposed to separate the cathode electrode 180 of a pair of sub-pixels disposed in the same column. An explanation of this will be given later in FIG. 5.

In the lower side of the transmission area TA there can be neither light-emitting element nor circuit element for driving a light-emitting element. To this end, the transmission area TA can include a structure in which layers 103, 105, 107, 110, 120, 125, 135, 145, 155 which are made of transparent material and insulating are laminated. By this structure, the transmission area TA can be a region with high light transmittance. In an example, the transmission area TA can further increase light transmittance by removing some of the bank 165, and/or the layer 155 of the layers; however, this is not exhaustive.

The pixel area PA can include a plurality of sub-pixels in which light-emitting elements EDs are disposed.

FIG. 4 is a plan view showing one sub-pixel disposed in area III of FIG. 2. FIG. 5 is a cross-sectional view taken along line IV-IV' in FIG. 4. Although FIG. 4 shows the first-first sub-pixel SP1a and the first-second sub-pixel SP1b of the first sub-pixel SP1, the second sub-pixel SP2, the third sub-pixel SP3, and the fourth sub-pixel SP4 can have substantially the same structure as the first sub-pixel SP1. In addition, for convenience of explanation, only the anode electrodes 160a, 160b, the first signal line SL1, the cathode contact portions 161a, 161b, the structures 183a, 183b, and the bank 165 are illustrated in FIG. 4.

Referring to FIGS. 4 and 5, on the substrate 100 a transistor array portion 200 can be disposed. The transistor array portion 200 can include a first transistor TR1, a second transistor TR2, and a capacitor CT.

The first transistor TR1 of the transistor array portion 200 can be disposed on the substrate 100. The substrate 110 can be comprised of an insulating material. For example, the substrate 100 can be comprised of glass, resin, or plastic material. The substrate 100 can be comprised of a flexible material.

The first transistor TR1 can include a first semiconductor layer 109, a first gate insulating layer 110, a first gate electrode 113a, and a first source/drain electrode 140.

Between the substrate 100 and the first transistor TR1 a plurality of buffer layers 103, 105, 107 can be disposed. The plurality of buffer layers 103, 105, 107 can include a first buffer layer 103, a second buffer layer 105, and a third buffer layer 107. The first buffer layer 103, the second buffer layer 105, and the third buffer layer 107 can overlap with each other in an up and down direction to cover the entire surface of the substrate 100. The first buffer layer 103, the second buffer layer 105, and the third buffer layer 107 can reduce or prevent the penetration of moisture, oxygen, or impurities through the substrate 100. Thereby, the transistors can be protected from moisture, oxygen or impurities penetrating through the substrate 100. The first buffer layer 103, the second buffer layer 105, and the third buffer layer 107 can include an inorganic insulating film including silicon oxide (SiOx) or silicon nitride (SiNx), but the embodiments of the present disclosure are not limited to this.

The first semiconductor layer 109 of the first transistor TR1 can include a silicon-based semiconductor material. For example, the first semiconductor layer 109 can include low-temperature polysilicon (LTPS). The first semiconductor layer 109 can include a channel region, a source region, and a drain region. The area of the first semiconductor layer 109 which overlaps with the first gate electrode 113a in an up and down direction can be the channel region. The source region and the drain region can be located on opposite sides of the channel region.

The first gate insulating layer 110 can be disposed between the first semiconductor layer 109 and the first gate electrode 113a. The first gate insulating layer 110 can be composed of silicon oxide (SiOx); however this is not exhaustive.

Between one of the buffer layers 103, 105, 107 and the first semiconductor layer 109 a light-blocking layer can be further included to block external light from being incident on the first semiconductor layer 109.

The first gate electrode 113a can be formed as a single layer or multiple layers comprised of any one or an alloy of molybdenum (Mo), aluminum (Al), chromium (Cr), gold (Au), titanium (Ti), nickel (Ni), neodymium (Nd), and copper (Cu).

At positions on the first gate insulating layer 110, which are different from the position where the first gate electrode 113a is formed, a plurality of first conductive patterns 113b, 113c can be disposed. The plurality of first conductive patterns 113b, 113c can include the same material as the first gate electrode 113a. Each of the plurality of first conductive patterns 113b, 113c can be disposed to be spaced apart from each other.

The first interlayer insulating layer 120 can be disposed on the first gate electrode 113a and the plurality of first conductive patterns 113b, 113c to cover them. The first interlayer insulating layer 120 can include an inorganic insulating material. For example, the first interlayer insulating layer 120 can include silicon nitride (SiNx).

On the first interlayer insulating layer 120 a second conductive pattern 123b can be disposed. The second conductive pattern 123b can be disposed in a different position from the area where the first transistor TR1 is disposed. For example, the second conductive pattern 123b can be disposed to overlap with one of the plurality of first conductive patterns 113b, 113c in an up and down direction. In an example, the first conductive pattern 113b and the second conductive pattern 123b can constitute a capacitor CT area.

On the first interlayer insulating layer 120 a first protective layer 125 can be disposed. The first protective layer 125 can be disposed, covering the second conductive pattern 123b. The first protective layer 125 can include an inorganic insulating material. For example, the first protective layer 125 can be composed of, but is not limited to, silicon oxide (SiOx).

On the first protective layer 125, the second transistor TR2 can be disposed. The second transistor TR2 can include a second semiconductor layer 129, a second gate insulating layer 130, a second gate electrode 133, and a second source/drain electrode 141.

The second semiconductor layer 129 of the second transistor TR2 can include an oxide semiconductor material. For example, the second semiconductor layer 129 can include, but is not limited to, an oxide semiconductor material such as indium-gallium-zinc-oxide (IGZO), indium-zinc-oxide (IZO), or indium-gallium-zinc-tin-oxide (IGZTO). The second semiconductor layer 129 can include a channel region, a source region, and a drain region. The area of the second semiconductor layer 129 which overlaps with the second gate electrode 133 in an up and down direction can be the channel region. The source region and the drain region can be located on opposite sides of the channel region. In an example, the second transistor TR2 can be a driving transistor for driving a sub-pixel.

The second gate insulating layer 130 can be disposed between the second semiconductor layer 129 and the second gate electrode 133. The second gate insulating layer 130 can be configured in a single layer or multiple layers of silicon oxide (SiOx) or silicon nitride (SiNx).

The second gate electrode 133 can be disposed on the second gate insulating layer 130. The second gate electrode 133 can be composed of, but is not limited to, the same material as the first gate electrode 113a.

The second interlayer insulating layer 135 can be disposed on the second gate electrode 133 to cover it. The second interlayer insulating layer 135 can include an inorganic insulating material. For example, the second interlayer insulating layer 135 can include silicon nitride (SiNx).

The first source/drain electrode 140 and the second source/drain electrode 141 can be disposed on the second interlayer insulating layer 135.

The first source/drain electrode 140 and the second source/drain electrode 141 can be disposed to be spaced apart from each other. For example, the first source/drain electrode 140 can be electrically connected to the first transistor TR1. The first source/drain electrode 140 can be electrically connected to the source region and drain region of the first semiconductor layer 109, respectively, through first via electrodes 137 penetrating through the second interlayer insulating layer 135, the first protective layer 125, the first interlayer insulating layer 120, and the first gate insulating layer 110.

For example, the second source/drain electrode 141 can be electrically connected to the second transistor TR2. The second source/drain electrode 141 can be electrically connected to the source region and drain region of the second semiconductor layer 129, respectively, through second via electrodes 139 penetrating through the second interlayer insulating layer 135.

The first source/drain electrode 140 and the second source/drain electrode 141 can be respectively formed as, but are not limited to, multiple layers comprised of any one or an alloy of molybdenum (Mo), aluminum (Al), chromium (Cr), gold (Au), titanium (Ti), nickel (Ni), neodymium (Nd), and copper (Cu). For example, the first source/drain electrode 140 and the second source/drain electrode 141 can be configured by disposing second metal layers on the upper surface and the lower surface of a first metal layer, respectively to interpose the first metal layer therebetween. For example, the first metal layer can include aluminum (Al), and the second metal layer can include titanium (Ti); however this is not exhaustive.

On the first source/drain electrode 140 and the second source/drain electrode 141 a planarization layer 145 can be disposed.

The planarization layer 145 can planarize the step differences caused by the lower circuit elements including the first and second transistors TR1, TR2. The planarization layer 145 can include an organic insulating material such as an acrylic resin, an epoxy resin, a phenolic resin, a polyamide resin, or a polyimide resin, and, however, there is no restriction to the kind of organic insulating material as long as it can planarize a step difference.

On the planarization layer 145 the connection electrode 150 can be disposed. The connection electrode 150 can be electrically connected to the second transistor TR2. The connection electrode 150 can be connected to the second source/drain electrode 141 through the third via electrode 147 penetrating through the planarization layer 145. And it can be electrically connected to the second transistor TR2 through the second source/drain electrode 141.

The connection electrode 150 can be formed as, but is not limited to, multiple layers comprised of any one or an alloy of molybdenum (Mo), aluminum (Al), chromium (Cr), gold (Au), titanium (Ti), nickel (Ni), neodymium (Nd), and copper (Cu). For example, the connection electrode 150 can be configured by disposing second metal layers on the upper surface and the lower surface of a first metal layer, respectively to interpose the first metal layer therebetween. For example, the first metal layer can include aluminum (Al), and the second metal layer can include titanium (Ti); however this is not exhaustive.

The connection electrode 150 can be disposed to overlap with the first-first sub-pixel SP1a and the first-second sub-pixel SP1b of the first sub-pixel SP1. For example, the connection electrode 150 can be disposed to extend from the first-first sub-pixel SP1a to the first-second sub-pixel SP1b. The connection electrode 150 can be disposed in a non-emission area so as not to overlap with the emission area. The connection electrode 150 can supply driving power from the second transistor TR2, which is a driving transistor, to the first-first sub-pixel SP1a and the first-second sub-pixel SP1b of the first sub-pixel SP1.

On the connection electrode 150 a second protective layer 155 can be disposed. The second protective layer 155 can include an inorganic insulating material. For example, the second protective layer 155 can be composed of, but is not limited to, silicon oxide (SiOx). The second protective layer 155 can include a trench portion 169a, 169b. The trench portion 169a, 169b can have a shape recessed in the thickness direction of the second protective layer 155. For example, the trench portion 169a, 169b can include a bottom surface and opposite sidewalls extending from the bottom surface. For example, the trench portion 169a, 169b can have a shape that surrounds the four outer sides of each of the first-first sub-pixel SP1a and the first-second sub-pixel SP1b.

On the second protective layer 155 a third protective layer 157 can be disposed. The third protective layer 157 can include an organic insulating material. For example, the third protective layer 157 can include, but is not limited to, an organic insulating material such as polyimide resin. The third protective layer 157 can also be referred to as an overcoating layer.

On the third protective layer 157 an anode electrode 160a, 160b and a cathode contact portion 161a, 161b can be disposed.

The anode electrode 160a, 160b can include a first-first anode electrode 160a disposed in the first-first sub-pixel SP1a and a first-second anode electrode 160b disposed in the first-second sub-pixel SP1b.

The anode electrode 160a, 160b can include a metal oxide such as indium tin oxide (ITO) or indium zinc oxide (IZO). Alternatively, the anode electrode 160a, 160b can include a multilayer structure including a reflective metal film formed of silver (Ag), aluminum (Al), gold (Au), nickel (Ni), chromium (Cr), and compounds thereof, but the embodiments of the present disclosure are not limited thereto. For example, the reflective layer can include APC (silver/palladium/copper alloy). In an example, the anode electrode 160a, 160b can be formed as triple layers comprised of ITO/APC/ITO. For example, the anode electrode 160a, 160b can also be referred to as a pixel electrode.

A portion of the anode electrode 160a, 160b can be configured as a fourth via electrode 159a, 159b penetrating through the second protective layer 155 to be electrically connected to the connection electrode 150. The fourth via electrode 159a, 159b can include a fourth-first via electrode 159a disposed in the first-first sub-pixel SP1a and a fourth-second via electrode 159b disposed in the first-second sub-pixel SP1b. The anode electrode 160a, 160b can be electrically connected to the second transistor TR2 through the connection electrode 150 connected to the fourth-first via electrode 159a and the fourth-second via electrode 159b.

The cathode contact portion 161a, 161b can be disposed on the same plane as the anode electrode 160a, 160b to be spaced apart from it. The cathode contact portion 161a, 161b can include a first-first cathode contact portion 161a disposed in the first-first sub-pixel SP1a and a first-second cathode contact portion 161b disposed in the first-second sub-pixel SP1b.

The cathode contact portion 161a, 161b can include, but is not limited to, the same material as the anode electrode 160a, 160b. In an example, the cathode contact portion 161a, 161b can include a conductive material. In the case where the cathode contact portion 161a, 161b includes the same material as the anode electrode 160a, 160b, they can be formed in the same process, thus simplifying the process steps. Referring to FIG. 1 and FIG. 4 together, the cathode contact portion 161a, 161b can be branched from the first signal line SL1 that supplies the power voltage provided from the power supply portion 30, and be provided to each sub-pixel; however, this is not exhaustive. In an example, the cathode contact portion 161a, 161b can extend in the row direction of the display area DA.

On the third protective layer 157 the bank 165 can be disposed. The bank 165 can distinguish sub-pixels from each other. Additionally, the bank 165 can prevent lights of different colors from being mixed and output between adjacent pixels. For this purpose, the bank 165 can be formed to cover the edge of the anode electrode 160a, 160b. Additionally, the bank 165 can be formed to cover the edge of each cathode contact portion 161a, 161b to distinguish the anode electrode 160a, 160b and the cathode contact portion 161a, 161b from each other. In addition, one end of the bank 165 can be configured to extend from the anode electrode 160a, 160b or the cathode contact portion 161a, 161b to cover the edge of the third protective layer 157 and to protrude more than the sidewall of the trench portion 169a, 169b.

A partial area of each of the anode electrode 160a, 160b and cathode contact portion 161a, 161b can be exposed through the bank hole, which can include a first open area OA1 and a second open area OA2, without being covered by the bank 165. Thereby, the first open area OA1 and the second open area OA2 can be disposed in the first-first sub-pixel SP1a and the first-second sub-pixel SP1b, respectively. Referring to FIG. 4, the first open area OA1 and the second open area OA2 can be disposed to be spaced apart from each other in the column direction. The first open area OA1 can be an emission area EA (FIG. 3). The remaining area excluding the emission area EA can be a non-emission area NEA (see FIG. 3).

The bank 165 can include, but is not limited to, an organic insulating film such as polyimide or epoxy. For example, the bank 165 can be composed of an organic material including a black pigment or the like. In the case where the bank 165 is composed of a material including black pigment or the like, it can be a black bank. In the case where the bank 165 is composed of a material including black pigment, light from the outside or light reflected from the outside can be blocked, thus further improving the brightness of the display apparatus.

On the anode electrode 160a, 160b an emission layer 170a, 170b can be disposed. The emission layer 170a, 170b can include a first-first emission layer 170a disposed in the first-first sub-pixel SP1a and a first-second emission layer 170b disposed in the first-second sub-pixel SP1b.

In an example, the emission layer 170a, 170b can include organic material that emits light of different color for each pixel. For example, the emission layer 170a, 170b can emit light of one color among red, green, blue, and white. In another example, the emission layer 170a, 170b can be comprised of organic material that emits white light, and display one color among red, green, or blue colors by a color filter.

The emission layer 170a, 170b can include a stack structure including a hole transporting layer (HTL), an emission material layer (EML), an electron transporting layer (ETL), a hole blocking layer (HBL), a hole injection layer (HIL), an electron blocking layer (EBL), and an electron injection layer (EIL). In the case where it includes the stack structure, the stack structure can include one or more stack structures. For example, one or more stack structures can further include a charge generation layer therebetween.

The emission layer 170a, 170b can be disposed on the anode electrode 160a, 160b exposed on the first open area OA1. The emission layer 170a, 170b can be disposed along the sidewall and upper surface of the bank 165, and be disposed continuously up to a partial area of the cathode contact portion 161a, 161b exposed in the second open area OA2. For example, the emission layer 170a, 170b can cover the sidewall of the bank 165 in the second open area OA2 while exposing the surface of the cathode contact portion 161a, 161b.

A portion of the emission layer 170a, 170b can be disposed on the bottom surface of the first-first trench portion 169a surrounding the outside of the first-first sub-pixel SP1a and the first-second trench portion 169b surrounding the outside of the first-second sub-pixel SP1b. The portion of the emission layer 170a, 170b disposed in the first-first trench portion 169a and the first-second trench portion 169b can be configured as a lower pattern 171a, 171b of the structure 183a, 183b.

The first-first trench portion 169a and the first-second trench portion 169b can have an undercut structure in which the sidewall is disposed in the inner side than the end of the bank 165. Thereby, the end of the bank 165 can have a shape protruding further than the sidewall of the trench portion 169a, 169b.

The emission layer 170a, 170b can be disposed as the lower pattern 171a, 171b only on the bottom surface of the trench portion 169a, 169b without being disposed on the sidewall. As a result, the first-first emission layer 170a disposed in the first-first sub-pixel SP1a can be separated from the first-second emission layer 170b disposed in the first-second sub-pixel SP1b by the break in continuity at the respective trench portion 169a, 169b.

Further, the emission layer 170a, 170b can be separated at the first open area OA1 and the second open area OA2. For example, the first-first emission layer 170a disposed in the first-first sub-pixel SP1a can have a break in its continuity at the sidewalls of the bank 165 to expose the upper surface of the first-first cathode contact portion 161a on the second open area OA2. Further, the first-second emission layer 170b disposed in the first-second sub-pixel SP1b can have a break in its continuity at the sidewalls of the bank 165 to expose the upper surface of the first-second cathode contact portion 161b on the second open area OA2. Thus, the emission layer 170a, 170b can be separated by the continuity of the emission layer being broken within the second open area OA2.

On the emission layer 170a, 170b a cathode electrode 180a, 180b can be disposed. The cathode electrode 180a, 180b can be formed to cover the emission layer 170a, 170b. The cathode electrode 180a, 180b can include a first-first cathode electrode 180a disposed in the first-first sub-pixel SP1a and a first-second cathode electrode 180b disposed in the first-second sub-pixel SP1b.

A light-emitting element ED1a, ED1b can include and be configured with the anode electrode 160a, 160b, the emission layer 170a, 170b, and the cathode electrode 180a, 180b. The light-emitting element ED1a, ED1b can include a first-first light-emitting element ED1a disposed in the first-first sub-pixel SP1a and a first-second light-emitting element ED1b disposed in the first-second sub-pixel SP1b. The first-first light-emitting element ED1a and the first-second light-emitting element ED1b can be, but are not limited to, organic light-emitting elements.

The cathode electrode 180a, 180b can include a metal oxide such as indium tin oxide (ITO) or indium zinc oxide (IZO), but the embodiments of the present disclosure are not limited thereto. Alternatively, the cathode electrode 180a, 180b can include a single-layer or multilayer structure including a reflective metal film formed of silver (Ag), aluminum (Al), gold (Au), nickel (Ni), chromium (Cr), and compounds thereof, but the embodiments of the present disclosure are not limited thereto.

The cathode electrode 180a, 180b can be disposed on the emission layer 170a, 170b disposed on the first open area OA1. The cathode electrode 180a, 180b can be disposed on the emission layer 170a, 170b disposed along the sidewalls and upper surfaces of the bank 165. The cathode electrode 180a, 180b can be connected to the exposed surface of the cathode contact portion 161a, 161b while covering the ends of the emission layer 170a, 170b in the second open area OA2.

A portion of the cathode electrode 180a, 180b can be disposed on the lower pattern 171a, 171b disposed in the first-first trench portion 169a and the first-second trench portion 169b. A portion of the cathode electrode 180a, 180b disposed in the first-first trench portion 169a and the first-second trench portion 169b can be configured as an upper pattern 181a, 181b of the structure 183a, 183b. Thereby, in the first-first trench portion 169a, there can be disposed a first-first structure 183a in which the first-first lower pattern 171a and the first-first upper pattern 181a are laminated, while, in the first-second trench portion 169b, there can be disposed a first-second structure 183b in which the first-second lower pattern 171b and the first-second upper pattern 181b are laminated.

Each of the first-first structure 183a and the first-second structure 183b can be disposed to surround the outside of each of a pair of sub-pixels SP1a, SP1b when viewed in a plan view. Each of the first-first structure 183a and the first-second structure 183b can have a rectangular ring shape with a space portion disposed in the inside; however, this is not exhaustive. The first open area OA1 and the second open area OA2 can be disposed in the inside space portion of each of the first-first structure 183a and the first-second structure 183b. The first open area OA1 and the second open area OA2 can be disposed to be spaced apart from each other in the column direction.

Since each of the first-first trench portion 169a and the first-second trench portion 169b has an undercut shape, no cathode electrode 180a, 180b can be disposed on the sidewalls of the first-first trench portion 169a and the first-second trench portion 169b.

In addition, the first-first cathode electrode 180a disposed in the first-first sub-pixel SP1a can be disconnected due to a break in continuity at the end of the bank 165 protruding further than the sidewall of the first-first trench portion 169a. In addition, the first-second cathode electrode 180b disposed in the first-second sub-pixel SP1b can be disconnected due to a break in continuity at the end of the bank 165 protruding further than the sidewall of the first-second trench portion 169b.

As a result, the first-first cathode electrode 180a disposed in the first-first sub-pixel SP1a can be configured to be separated from the first-second cathode electrode 180b disposed in the first-second sub-pixel SP1b by the break in continuity at the respective trench portion 169a, 169b.

The cathode electrode 180a, 180b can extend from the first open area OA1 to the second open area OA2. A portion of the surface of the cathode contact portion 161a, 161b can be exposed in the second open area OA2. The cathode electrode 180a, 180b extended to the second open area OA2 can be brought into contact with the entire surface of the exposed area of the cathode contact portion 161a, 161b while forming a contact area. The cathode electrode 180a, 180b can be electrically connected to the cathode contact portion 161a, 161b by the contact area.

The cathode electrode 180a, 180b can be disposed to cover the exposed area of the cathode contact portion 161a, 161b, so that the surface area in contact with the cathode contact portion 161a, 161b can increase, thus reducing resistance. As the resistance of the cathode electrode 180a, 180b decreases, the current consumed at the same power supply voltage can be reduced. Thereby, the display apparatus can be driven at low power, which has the effect of reducing power consumption. Further, when the resistance of the cathode electrode 180a, 180b is reduced, the consumed current is reduced to prevent the phenomenon of voltage drop, thereby advantageously reducing the occurrence of brightness deviation by location in the display area.

Referring to FIG. 4 together, the first-first cathode electrode 180a can be electrically connected to the first-first cathode contact portion 161a branched from the first signal line SL1. In addition, the first-second cathode electrode 180b can be electrically connected to the first-second cathode contact portion 161b branched from the first signal line SL1 and spaced apart from the first-first cathode contact portion 161a. With this configuration, the pair of first-first sub-pixel SP1a and first-second sub-pixel SP1b disposed in the first sub-pixel SP1 can each receive power voltage from the power supply portion 30 (see FIG. 1) through different cathode contact portions 161a, 161b.

Besides, the pair of first-first sub-pixel SP1a and first-second sub-pixel SP1b disposed in the first sub-pixel SP1 can be supplied with driving power from one second transistor TR2 through the connection electrode 150.

The pair of first-first sub-pixel SP1a and first-second sub-pixel SP1b can be supplied with the driving power from one second transistor TR2 through the connection electrode 150, while the first-first cathode electrode 180a and the first-second cathode electrode 180b that are separated from each other can be separately supplied with the power voltage. Thereby, even if any one of the first-first sub-pixel SP1a and the first-second sub-pixel SP1b has a defect and does not light up, the other one can operate normally. Therefore, the corresponding first sub-pixel SP1a can operate normally.

For example, a defect can occur in the first-first sub-pixel SP1a among the first-first sub-pixel SP1a and the first-second sub-pixel SP1b of the first sub-pixel SP1. In this case, the driving power can be supplied from one second transistor TR2 through the connection electrode 150 to the first-second sub-pixel SP1b, and the power voltage can be supplied to the first-second cathode electrode 180b electrically connected to the first-second cathode contact portion 161b, and so the first sub-pixel SP1 can emit light normally. Thereby, since a repair process through laser cutting or the like can be omitted, process steps can be optimized, thereby improving the yield of the display apparatus. In addition, even if a defect occurs in a portion of a pair of sub-pixels emitting light of the same color, the corresponding sub-pixel can operate normally, thereby improving the reliability of the display apparatus. Consequently, it is possible to prevent the dark spot defect occurrence in the display area, thereby increasing the user's screen immersion and thus the reliability of the product.

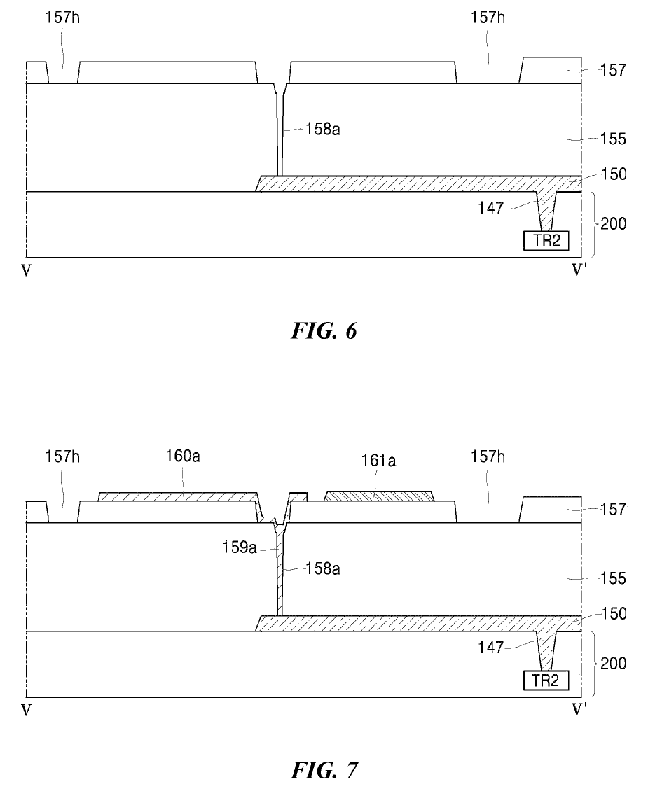

FIGS. 6-13 are views showing a method for manufacturing a display apparatus according to an embodiment of the present disclosure. Specifically, FIGS. 6-13 are cross-sectional views taken along line V-V' in FIG. 4. For convenience of explanation, FIGS. 6-13 briefly illustrate structures disposed in the lower side of the second protective layer 155 as a transistor array portion 200. Additionally, for convenience of explanation, in the transistor array portion 200, only the second transistor TR2 is briefly illustrated. Besides, although FIGS. 6-13 illustrate the first-first sub-pixel of the first sub-pixel as an example, the first-second sub-pixel and other sub-pixels have the substantially same configuration as the first-first sub-pixel.

Referring to FIG. 6, the connection electrode 150 can be disposed on the transistor array portion 200. The transistor array portion 200 can include the first transistor TR1 (see, FIG. 5), the second transistor TR2, and the capacitor CT (see, FIG. 5). In an example, the second transistor TR2 can be, but is not limited to, a driving transistor. The connection electrode 150 can be electrically connected to the second transistor TR2 through the third via electrode 147. The second protective layer 155 and the third protective layer 157 can be formed on the connection electrode 150. The second protective layer 155 can include an inorganic insulating material. For example, the second protective layer 155 can include silicon oxide (SiOx). The third protective layer 157 can include an organic insulating material. For example, the third protective layer 157 can include polyimide resin.

The third protective layer 157 can include an opening pattern 157h that exposes a portion of the surface of the second protective layer 155. In a partial area of the opening pattern 157h, there can be formed a via hole 158a that penetrates through the second protective layer 155 and exposes a portion of the surface of the connection electrode 150.

Referring to FIG. 7, the first-first anode electrode 160a and the first-first cathode contact portion 161a can be formed on the third protective layer 157. The first-first anode electrode 160a and the first-first cathode contact portion 161a can be formed on the same plane to be spaced apart from each other. The first-first anode electrode 160a and the first-first cathode contact portion 161a can include and be formed of the same material. In this case, they can be formed in the same process, and so the process steps can be simplified.

A portion of the first-first anode electrode 160a can be configured as the fourth-first via electrode 159a that fills the via hole 158a penetrating through the second protective layer 155, and is electrically connected to the connection electrode 150.

Referring to FIG. 8, the bank 165 can be formed on the second protective layer 155. The bank 165 can be formed to cover the edges of each of the first-first anode electrode 160a and the first-first cathode contact portion 161a. The bank 165 can include a bank hole exposing portions of the surfaces of the first-first anode electrode 160a and the first-first cathode contact portion 161a. The bank hole can include the first open area OA1 and the second open area OA2. The first open area OA1 can expose a portion of the surface of the first-first anode electrode 160a, and the second open area OA2 can expose a portion of the surface of the first-first cathode contact portion 161a. The bank 165 can be disposed between the first-first anode electrode 160a and the first-first cathode contact portion 161a which are disposed to be spaced apart from each other. In an example, the bank 165 can be formed to cover the exposed surface of the fourth-first via electrode 159a.

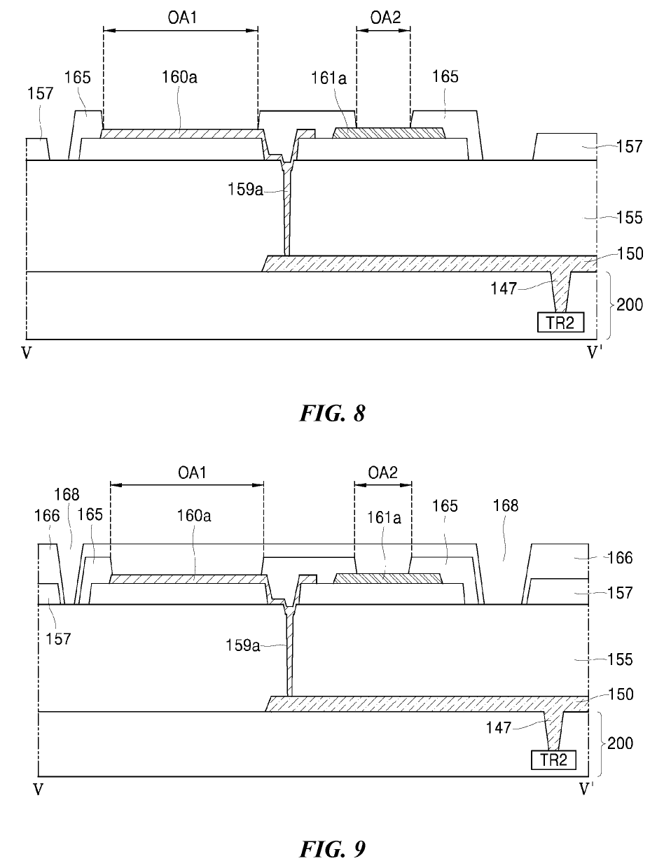

Referring to FIG. 9, the mask pattern 166 can be formed. The mask pattern 166 can be formed by applying a photoresist material and performing a photolithography process and development process. The mask pattern 166 can include an opening hole 168 surrounding the outside of the sub-pixel. In an example, the opening hole 168 can include a first portion near the first open area OA1 and a second portion near the second open area OA2. The first and second portions of the opening hole 168 can have different widths; however, this is not exhaustive. For example, the first portion and the second portion can be of the same width.

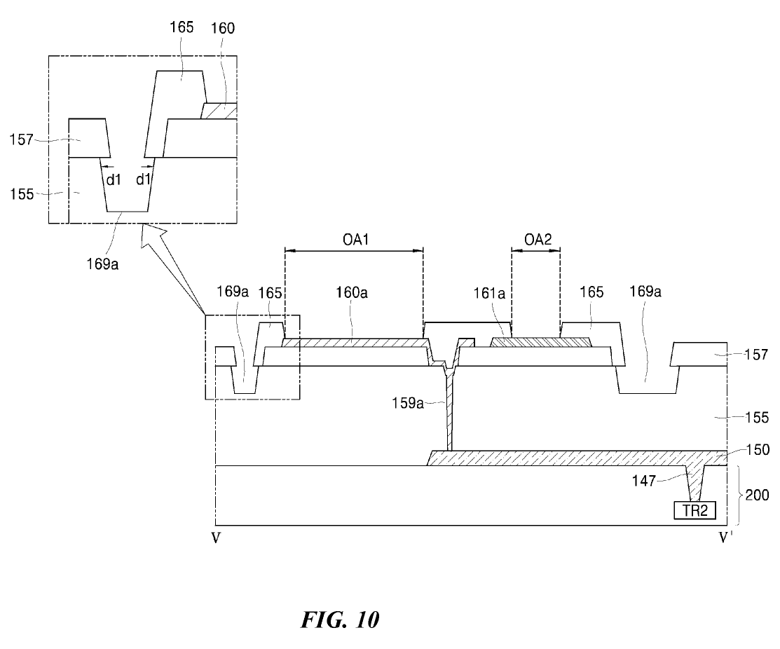

Referring to FIGS. 9 and 10 together, an etching process using the mask pattern 166 as an etching mask can be performed to form the first-first trench portion 169a within the second protective layer 155. The etching process can be performed in a wet etching method.

The first-first trench portion 169a including the bottom surface and both sidewalls can be formed by the wet etching process in which the second protective layer 155 is etched from the surface in the thickness direction. The second protective layer 155 can be over-etched into an undercut shape relative to the bank 165 by the wet etching process which proceeds isotropically. For example, the second protective layer 155 can be further etched inwardly by a first distance d1 from one end of the bank 165 and from one end of the third protective layer 157. Thereby, the one end of each of the bank 165 and the third protective layer 157 can be formed in a shape that protrudes more than the sidewall of the first-first trench portion 169a. Next, the mask pattern 166 is removed.

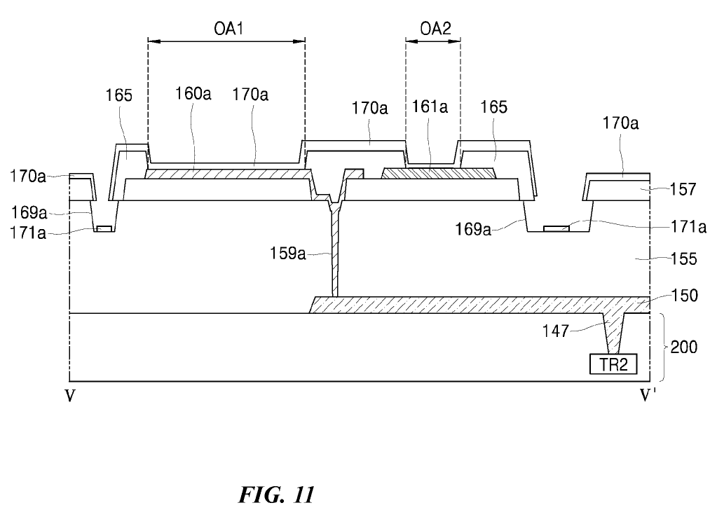

Referring to FIG. 11, the first-first emission layer 170a can be formed on the first open area OA1 and the second open area OA2. The first-first emission layer 170a can include an organic material. The first-first emission layer 170a can be formed on the exposed surface of the first-first anode electrode 160a and the exposed surface of the first-first cathode contact portion 161a. The first-first emission layer 170a can be formed to extend from the first open area OA1 to the second open area OA2. The first-first emission layer 170a can be formed on the upper surface of the bank 165 and the upper surface of the third protective layer 157, respectively.

A portion of the first-first emission layer 170a can be formed on the bottom surface of the first-first trench portion 169a. Since the first-first trench portion 169a has the undercut shape, the first-first emission layer 170a may not be formed on the sidewalls of the first-first trench portion 169a. Thereby, the first-first emission layer 170a can be separated by the continuity being broken between the bank 165 and the third protective layer 157 with the first-first trench portion 169a interposed therebetween. The portion of the first-first emission layer 170a disposed on the bottom surface of the first-first trench portion 169a can be formed as the lower pattern 171a.

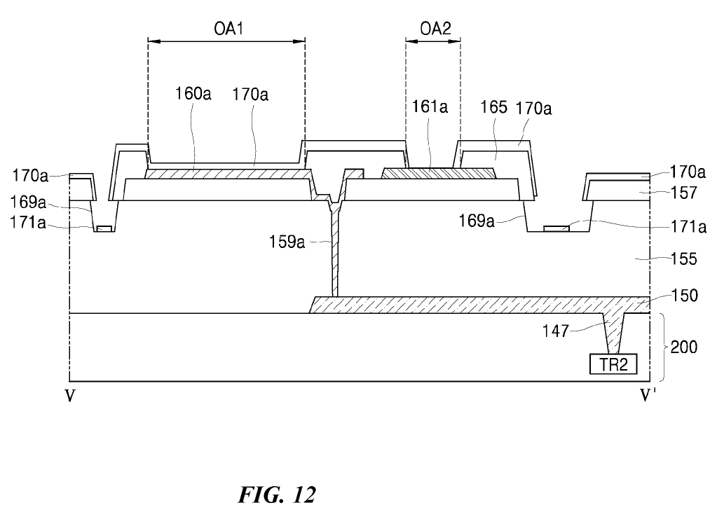

Referring to FIG. 12, a removal process is performed to selectively remove a portion of the first-first emission layer 170a which is formed on the exposed surface of the first-first cathode contact portion 161a. The removal process can selectively remove, by using a laser drilling method, only the portion of the first-first emission layer 170a which is formed on the exposed surface of the first-first cathode contact portion 161a.

Thereby, a portion of the surface of the first-first cathode contact portion 161a can be exposed in the second open area OA2. In an example, the first-first cathode contact portion 161a can have the same surface area as the second open area OA2. Besides, the first-first emission layer 170a can have a break in its continuity at the sidewalls of the bank 165 covering the edges of the first-first cathode contact portion 161a in the second open area OA2. Thereby, the first-first emission layer 170a can be separated at the first open area OA1 and the second open area OA2.

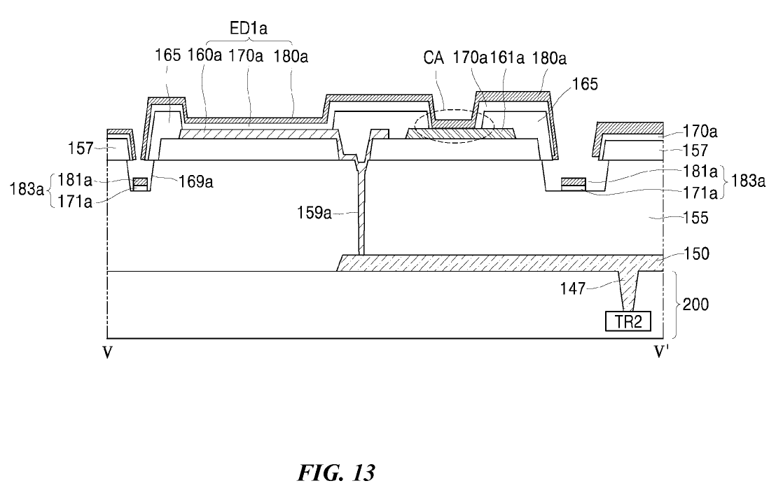

Referring to FIG. 13, the first-first cathode electrode 180a can be formed. The first-first cathode electrode 180a can be formed on the first-first emission layer 170a. Thereby, it is possible to construct, in the first-first sub-pixel, the first-first light-emitting element ED1a including the first-first anode electrode 160a, the first-first emission layer 170a, and the first-first cathode electrode 180a.

The first-first cathode electrode 180a can be formed to extend from the first open area OA1 to the second open area OA2. A portion of the first-first cathode electrode 180a can be configured as the upper pattern 181a by being disposed on the lower pattern 171a disposed on the bottom surface of the first-first trench portion 169a. Thereby, the first-first structure 183a including the lower pattern 171a and the upper pattern 181a can be formed on the bottom surface of the first-first trench portion 169a. The first-first structure 183a can be formed to surround the outside of the first-first sub-pixel SP1a when viewed in a plan view. For example, the first-first structure 183a can have a rectangular ring shape with a space portion disposed in the inside. Alternatively, the first structure 183a can have a polygonal ring shape.

The first-first cathode electrode 180a can be separated by the continuity being broken between the bank 165 and the third protective layer 157 with the first-first trench portion 169a interposed therebetween. Thereby, the first-first cathode electrode 180a can be separated from the neighboring other cathode electrode with the first-first trench portion 169a interposed therebetween.

The first-first cathode electrode 180a can form the contact area CA by being brought into contact with the entire exposed surface area of the first-first cathode contact portion 161a in the second open area OA2. The first-first cathode electrode 180a can be formed to cover the exposed surface area of the first-first cathode contact portion 161a, so that the contact surface area increases, thus reducing the resistance.

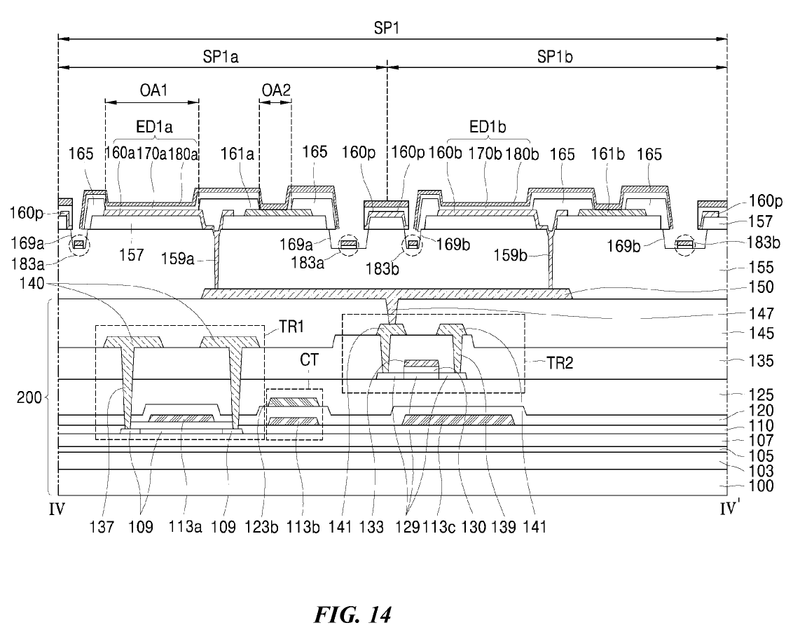

FIG. 14 is a view according to a modified example of an embodiment of the present disclosure. Specifically, FIG. 14 is a cross-sectional view taken along line IV-IV' in FIG. 4. The display apparatus according to FIG. 14 is identical to the display apparatus of FIG. 5 except that it includes configuring a protrusion pattern 160p covering one or more edges of the third protective layer 157, and therefore, a duplicate description will be omitted. In FIG. 14, the same reference symbols are used to designate like components as in FIG. 5.

Referring to FIG. 14, when the protrusion pattern 160p is formed to have a protruding shape while covering the one or more edges of the third protective layer 157, it can be configured in a shape protruding further than the sidewall of the trench portion 169a, 169b. In this case, the emission layer 170a, 170b can be disposed along the shape of the protrusion pattern 160p. The cathode electrode 180a, 180b can be disposed on the emission layer 170a, 170b. Thereby, there can be an effect of preventing the emission layer 170a, 170b and the cathode electrode 180a, 180b from being formed on the sidewall of the trench portion 169a, 169b.

Consequently, there is an advantage in that the separated cathode electrode 180a, 180b can be configured more easily.

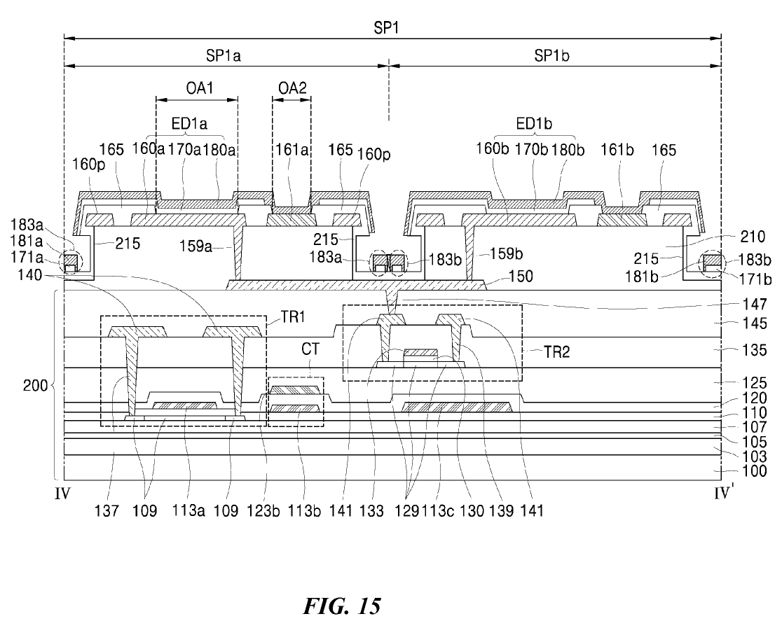

FIG. 15 is a view according to another embodiment of the present disclosure. FIG. 15 is a cross-sectional view taken along line IV-IV' in FIG. 4. In FIG. 15, the same reference symbols are used to designate like components as in FIG. 5, and any repetitive detailed description thereof will be omitted or simplified.

Referring to FIG. 15, the connection electrode 150 can be disposed on the planarization layer 145 of the substrate 100 with the transistor array portion 200 disposed thereon. The transistor array portion 200 can include a first transistor TR1, a second transistor TR2, and a capacitor CT. The connection electrode 150 can be electrically connected to the second transistor TR2 through the third via electrode 147.

On the connection electrode 150 a step difference planarization layer 210 can be disposed. The step difference planarization layer 210 can planarize the step difference caused by the connection electrode 150. The step difference planarization layer 210 can include an organic insulating material.

The step difference planarization layer 210 can include a trench portion 215 having a shape recessed in the thickness direction. The trench portion 215 can include a bottom surface and opposite sidewalls extending from the bottom surface. In an example, the trench portion 215 can expose a portion of the surface of the connection electrode 150 in the boundary area between the first-first sub-pixel SP1a and the first-second sub-pixel SP1b. In an example, the trench portion 215 can have a shape that surrounds the four outer sides of each of the first-first sub-pixel SP1a and the first-second sub-pixel SP1b, in plan view.

The anode electrode 160a, 160b and the cathode contact portion 161a, 161b can be disposed on the step difference planarization layer 210. A portion of the anode electrode 160a, 160b can be configured as a fourth via electrode 159a, 159b penetrating through the step difference planarization layer 210 to be electrically connected to the connection electrode 150. Thereby, the connection electrode 150 can electrically connect the second transistor TR2 with the first-first anode electrode 160a of the first-first sub-pixel SP1a and the first-second anode electrode 160b of the first-second sub-pixel SP1b.

The anode electrode 160a, 160b and the cathode contact portion 161a, 161b can be disposed on the same plane to be spaced apart from each other.

Additionally, a plurality of protrusion patterns 160p can be disposed on the step difference planarization layer 210 to be spaced apart from the anode electrode 160a, 160b and the cathode contact portion 161a, 161b, respectively. One of the plurality of protrusion patterns 160p can be disposed to be spaced apart from the anode electrode 160a, 160b. Besides, another one of the plurality of protrusion patterns 160p can be disposed to be spaced apart from the cathode contact portion 161a, 161b. For example, the plurality of protrusion patterns 160p can protrude toward the trench portion 215 from the upper edge of the step difference planarization layer 210 with the trench portion 215 disposed therein. For example, the plurality of protrusion patterns 160p can have a shape protruding further than the sidewall of the trench portion 215.

The cathode contact portion 161a, 161b and the plurality of protrusion patterns 160p can include, but are not limited to, the same material as the anode electrode 160a, 160b. In an example, the cathode contact portion 161a, 161b and the plurality of protrusion patterns 160p can include a conductive material. In the case where the cathode contact portion 161a, 161b and the plurality of protrusion patterns include the same material as the anode electrode 160a, 160b, they can be formed in the same process, thus simplifying the process steps.

The bank 165 can be disposed on the step difference planarization layer 210. The bank 165 can include, but is not limited to, an inorganic insulating material. The bank 165 can be formed to cover the edges of each of the anode electrode 160a, 160b and the cathode contact portion 161a, 161b. Besides, the bank 165 can be disposed on the trench portion 215 while covering the plurality of protrusion patterns 160p. For example, the bank 165 can be disposed on the sidewalls and bottom surface of the trench portion 215. Thereby, the bank 165 can cover a portion of the surface of the connection electrode 150 which is exposed by the trench portion 215 in the boundary area between the first-first sub-pixel SP1a and the first-second sub-pixel SP1b.

The bank 165 can include the first open area OA1 exposing a portion of the surface of the anode electrode 160a, 160b and the second open area OA2 exposing a portion of the surface of the cathode contact portion 161a, 161b. The first open area OA1 and the second open area OA2 can be disposed to be spaced apart from each other in the column direction. The first open area OA1 can be an emission area. In an example, the remaining area except the first open area OA1 can be a non-emission area.

On the anode electrode 160a, 160b an emission layer 170a, 170b can be disposed. The emission layer 170a, 170b can be disposed on the anode electrode 160a, 160b exposed on the first open area OA1. The emission layer 170a, 170b can be disposed along the sidewalls and upper surface of the bank 165. The emission layer 170a, 170b can be disposed on the upper surface of the bank 165 in the second open area OA2 so as to expose a portion of the surface of the cathode contact portion 161a, 161b.

A portion of the emission layer 170a, 170b can be disposed on the bottom surface of the trench portion 215. The portion of the emission layer 170a, 170b disposed in the trench portion 215 can be configured as the lower pattern 171a, 171b of the structure 183a, 183b. The trench portion 215 can have an undercut structure in which the sidewalls are disposed closer to the inside than the ends of the plurality of protrusion patterns 160p. Thereby, the end of the bank 165 covering the plurality of protrusion patterns 160p can have a shape protruding further than the sidewall of the trench portion 215. Therefore, the emission layer 170a, 170b may not be disposed on the sidewall of the trench portion 215. As a result, the emission layers 170a, 170b disposed in the respective sub-pixels SP1a, SP1b can be separated from each other by the break in continuity at the respective trench portion 215.

On the emission layer 170a, 170b a cathode electrode 180a, 180b can be disposed. The cathode electrode 180a, 180b can be disposed on the emission layer 170a, 170b disposed on the first open area OA1.

A portion of the cathode electrode 180a, 180b can be configured as the upper pattern 181a, 181b of the structure 183a, 183b which is disposed on the lower pattern 171a, 171b of the trench portion 215. Thereby, the structure 183a, 183b in which the lower pattern 171a, 171b and the upper pattern 181a, 181b are laminated can be disposed in each trench portion 215. In an example, the upper pattern 181a, 181b can be shaped to cover the upper surface and sidewalls of the lower pattern 171a, 171b.

Further, since the cathode electrodes 180a, 180b are not deposited on the sidewalls of the trench portion 215, they can be separated from each other in the bank 165 disposed in the boundary area between the first-first sub-pixel SP1a and the first-second sub-pixel SP1b. As a result, the first-first cathode electrode 180a disposed in the first-first sub-pixel SP1a can be configured to be separated from the first-second cathode electrode 180b disposed in the first-second sub-pixel SP1b by the break in continuity at the respective trench portion 215.

The cathode electrode 180a, 180b can form a contact area that is connected to the exposed surface of the cathode contact portion 161a, 161b while covering the ends of the emission layer 170a, 170b which are separated from each other in the second open area OA2. The cathode electrode 180a, 180b can be electrically connected to the cathode contact portion 161a, 161b by the contact area.

The cathode electrode 180a, 180b can be disposed to cover the exposed area of the cathode contact portion 161a, 161b, so that the surface area in contact with the cathode contact portion 161a, 161b can increase, thus reducing resistance. Further, the first-first cathode electrode 180a disposed in the first-first sub-pixel SP1a and the first-second cathode electrode 180b disposed in the first-second sub-pixel SP1b can be separately supplied with the power voltage. Thereby, even if a defect occurs in any one of the first-first sub-pixel SP1a and the first-second sub-pixel SP1b, the other one can operate normally without performing a repair process, so that the corresponding sub-pixel can be determined to be normal. Thereby, since a repair process through laser cutting or the like can be omitted, process steps can be optimized, thereby improving the yield of the display apparatus.

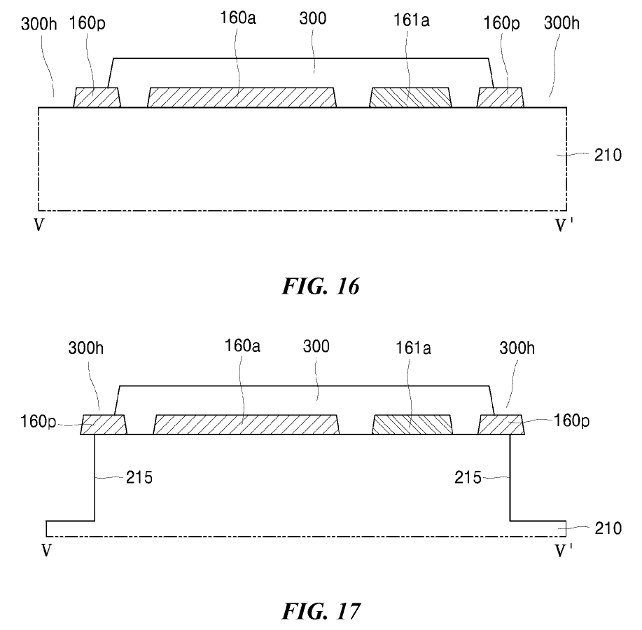

FIGS. 16-21 are views showing a method for manufacturing a display apparatus according to another embodiment of the present disclosure. FIGS. 16-21 are cross-sectional views taken along line V-V' in FIG. 4. For convenience of explanation, FIGS. 16-21 briefly illustrate only the step difference planarization layer 210 in the transistor array portion 200. Besides, although FIGS. 16-21 illustrate the first-first sub-pixel of the first sub-pixel as an example, the first-second sub-pixel and other sub-pixels have the substantially same configuration as the first-first sub-pixel.

Referring to FIG. 16, the first-first anode electrode 160a, the first-first cathode contact portion 161a, and a plurality of protrusion patterns 160p can be formed on the step difference planarization layer 210. The first-first anode electrode 160a, the first-first cathode contact portion 161a, and the plurality of protrusion patterns 160p can include and be formed of the same material. In this case, they can be formed in the same process, and so the process steps can be simplified.

In a subsequent step, a mask pattern 300 can be formed on the step difference planarization layer 210. The mask pattern 300 can be formed by patterning a photoresist material. The mask pattern 300 can include an opening hole 300h exposing a portion of the surface of the plurality of protrusion patterns 160p. The first-first anode electrode 160a and the first-first cathode contact portion 161a can be blocked by the mask pattern 300.

Referring to FIG. 17, the trench portion 215 can be formed within the step difference planarization layer 210 by performing an etching process in which a portion exposed through the opening hole 300h is etched using the mask pattern 300 as an etching mask. By the etching process, the step difference planarization layer 210 can be over-etched into an undercut shape with respect to the plurality of protrusion patterns 160p. Since the step difference planarization layer 210 and the protrusion pattern 160p have different etching speeds, they can be formed in an undercut shape. For example, the protrusion pattern 160p can have a relatively slower etching speed than the step difference planarization layer 210. Thereby, the step difference planarization layer 210 can be etched further inwardly from one end of each of the plurality of protrusion patterns 160p. Consequently, one end of each of the plurality of protrusion patterns 160p can be formed in a shape that protrudes further than the sidewall of the trench portion 215. Next, the mask pattern 300 is removed.

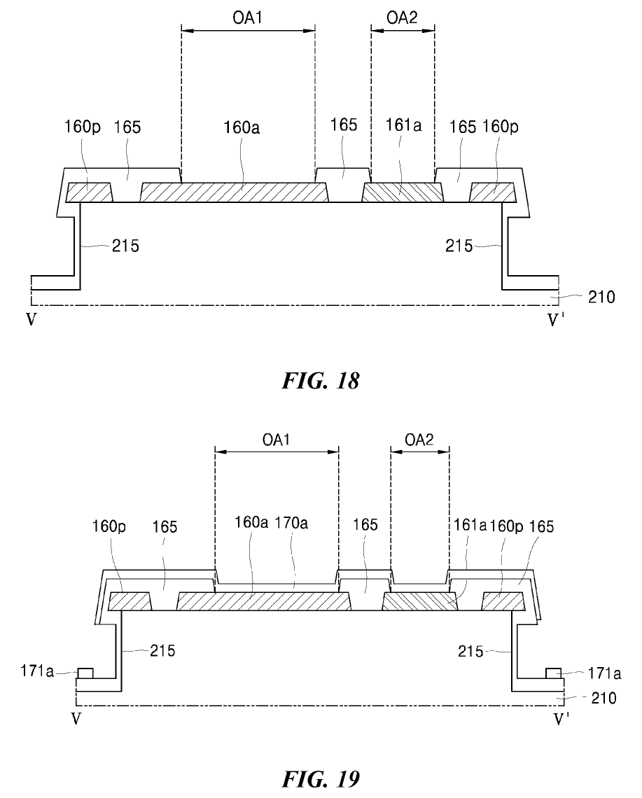

Referring to FIG. 18, the bank 165 can be formed on the step difference planarization layer 210. The bank 165 can be formed to cover the edges of each of the first-first anode electrode 160a and the first-first cathode contact portion 161a. The bank 165 can include the first open area OA1 exposing a portion of the surface of the anode electrode 160a and the second open area OA2 exposing a portion of the surface of the cathode contact portion 161a. The bank 165 can be disposed between the first-first anode electrode 160a and the first-first cathode contact portion 161a which are disposed to be spaced apart from each other.

The bank 165 can include an inorganic insulating material. Thereby, the bank 165 can be formed on both sidewalls and the bottom surface of the trench portion 215 while covering the plurality of protrusion patterns 160p.

Referring to FIG. 19, the first-first emission layer 170a can be formed on the first open area OA1 and the second open area OA2. The first-first emission layer 170a can include an organic material. The first-first emission layer 170a can be formed on the exposed surface of the first-first anode electrode 160a and the exposed surface of the first-first cathode contact portion 161a. The first-first emission layer 170a can be formed to extend from the first open area OA1 to the second open area OA2. The first-first emission layer 170a can extend along the upper surface and sidewalls of the bank 165.

A portion of the first-first emission layer 170a can be formed on the bottom surface of the trench portion 215. Since the plurality of protrusion patterns 160p have a shape that protrudes more than the sidewall of the trench portion 215, the first-first emission layer 170a may not be formed on the sidewall of the trench portion 215. Therefore, the first-first emission layer 170a can be separated at the edge of the bank 165. A portion of the first-first emission layer 170a disposed on the bottom surface of the trench portion 215 can be formed as the lower pattern 171a.

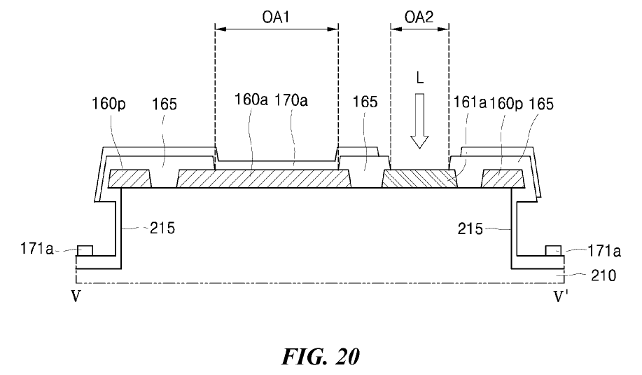

Referring to FIG. 20, only the portion of the first-first emission layer 170a which is formed on the exposed surface of the first-first cathode contact portion 161a can be selectively removed therefrom using the laser drilling method L. Thereby, a portion of the surface of the first-first cathode contact portion 161a can be exposed in the second open area OA2. In an example, the first-first cathode contact portion 161a can have the same surface area as the second open area OA2. Besides, the first-first emission layer 170a can have a break in its continuity at the upper surface of the bank 165 covering the edges of the first-first cathode contact portion 161a in the second open area OA2. Thereby, the first-first emission layer 170a can be separated at the second open area OA2 from the portion formed on the first open area OA1.

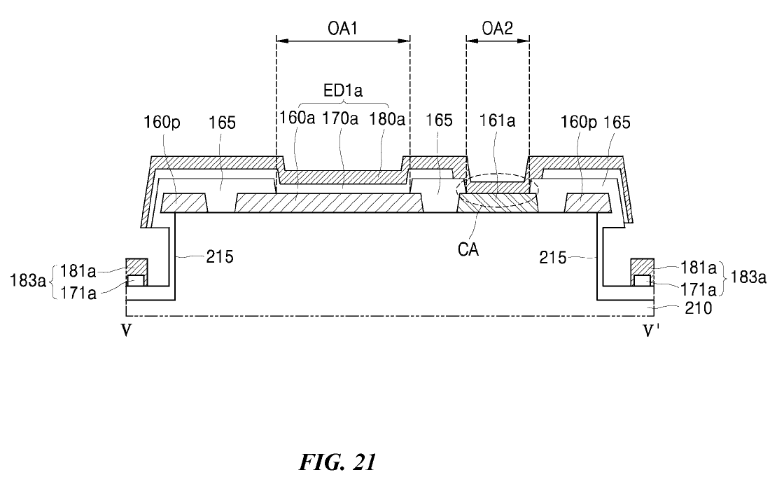

Referring to FIG. 21, the first-first cathode electrode 180a can be formed. The first-first cathode electrode 180a can be formed on the first-first emission layer 170a. Thereby, it is possible to construct, in the first-first sub-pixel, the first-first light-emitting element ED1a including the first-first anode electrode 160a, the first-first emission layer 170a, and the first-first cathode electrode 180a.

The first-first cathode electrode 180a can be formed to extend from the first open area OA1 to the second open area OA2. A portion of the first-first cathode electrode 180a can be configured as the upper pattern 181a by being disposed on the lower pattern 171a disposed on the bottom surface of the first-first trench portion 169a. Thereby, the first-first structure 183a including the lower pattern 171a and the upper pattern 181a can be formed on the bottom surface of the first-first trench portion 169a. Referring to FIG. 4 together, the first-first structure 183a can be formed to surround the outside of the first-first sub-pixel SP1a when viewed in a plan view. For example, the first-first structure 183a can have a rectangular ring shape with a space portion disposed in the inside. Alternatively, the first structure 183a can have a polygonal ring shape.

The first-first cathode electrode 180a can be separated by the continuity being broken with the trench portion 215 interposed therebetween. Thereby, the first-first cathode electrode 180a can be separated from the neighboring other cathode electrode. The first cathode electrode 180a and the other cathode electrode, which are separated from each other, can be supplied separately with power voltage. Consequently, even if a defect occurs in a sub-pixel, the power voltage can be supplied to the other sub-pixel with no defect to enable it to emit light, thus allowing the sub-pixel to operate normally.

The first-first cathode electrode 180a can form the contact area CA by being brought into contact with the entire exposed surface area of the first-first cathode contact portion 161a in the second open area OA2. The first-first cathode electrode 180a is formed to cover the exposed surface area of the first-first cathode contact portion 161a, thereby increasing the contact area and thus having an effect of reducing resistance.

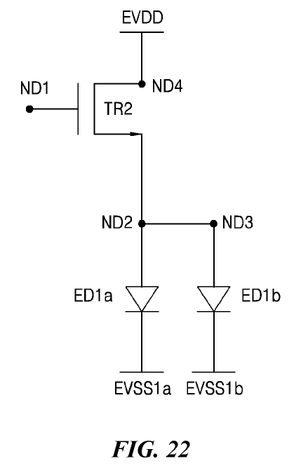

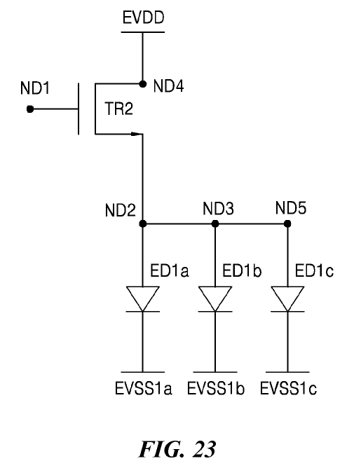

FIGS. 22 and 23 are equivalent circuit diagrams of one sub-pixel of a display apparatus according to embodiments of the present disclosure. For convenience of explanation, only a second transistor and light-emitting elements are shown in FIGS. 22 and 23. FIG. 23 is identical to the equivalent circuit illustrated in FIG. 22 except that it further includes a light-emitting element ED1c, so repetitive detailed description will be omitted or may be briefly provided.

Referring to FIG. 22, each of the plurality of sub-pixels according to embodiments of the present disclosure can include a second transistor TR2 and light-emitting elements ED1a, ED1b. The light-emitting elements ED1a, ED1b can be disposed in a pair of sub-pixels emitting one color. The light-emitting elements ED1a, ED1b disposed in the pair of sub-pixels can include a first-first light-emitting element ED1a as a main light-emitting element and a first-second light-emitting element ED1b as a redundancy light-emitting element. Each light-emitting element ED1a, ED1b can include an anode electrode, an emission layer, and a cathode electrode. The first-first light-emitting element ED1a of the light-emitting elements ED1a, ED1b, which is a main light-emitting element, can be disposed in a main sub-pixel of the pair of sub-pixels, and the first-second light-emitting element ED1b thereof, which is a redundancy light-emitting element, can be disposed in a redundancy sub-pixel of the pair of sub-pixels.

In an example, the second transistor TR2 can be a driving transistor for driving the light-emitting elements ED1a, ED1b. The second transistor TR2 can include a first node ND1, a second node ND2, a third node ND3, and a fourth node ND4. The first node ND1 of the second transistor TR2 can be a gate node. The first node ND1 of the second transistor TR2 can be electrically connected to a scan line of the second signal lines SL2. The second node ND2 and the third node ND3 of the second transistor TR2 can be the source node or the drain node of a transistor.

The second node ND2 and the third node ND3 of the second transistor TR2 can be electrically connected to the anode electrodes of the light-emitting elements ED1a, ED1b. Thereby, one transistor can be connected to at least two light-emitting elements ED1a, ED1b which emit light of the same color. The fourth node ND4 of the second transistor TR2 can be electrically connected to a power line of the first signal lines SL1, which supplies a high-potential power voltage EVDD.

The cathode electrodes of the light-emitting elements ED1a, ED1b can be separated from each other, so that low-potential power supply voltages EVSS1a, EVSS1b can be applied to them, respectively. For example, the cathode electrodes of the light-emitting elements ED1a, ED1b can be connected respectively to the cathode contact portions disposed according to any one of the embodiments of FIG. 5, FIG. 14, and FIG. 15 of the present disclosure, so that the low-potential power supply voltages EVSS1a, EVSS1b can be applied to them, respectively. Thereby, the light-emitting elements ED1a, ED1b can be connected in parallel. The cathode electrodes of the light-emitting elements ED1a, ED1b can be separated from each other by the structure 183a, 183b disposed according to any one of the embodiments of FIG. 5, FIG. 14, and FIG. 15 of the present disclosure.

Referring to FIG. 23, each of a plurality of sub-pixels disposed in a display area of a display apparatus according to embodiments of the present disclosure can further include a first-third light-emitting element ED1c in one sub-pixel, which emits light of the same color. For this purpose, the second node ND2, the third node ND3, and the fifth node ND5 of the second transistor TR2 can be electrically connected to the anode electrodes of the light-emitting elements ED1a, ED1b, ED1c. Thereby, one transistor can be electrically connected to three light-emitting elements ED1a, ED1b, ED1c which emit light of the same color. However, this is not exhaustive. For example, four light-emitting elements emitting light of the same color can be electrically connected to one transistor.

Further, the cathode electrodes of the light-emitting elements ED1a, ED1b, ED1c can be separated from each other, so that low-potential power supply voltages EVSS1a, EVSS1b, EVSS1c can be applied to them, respectively. Thereby, the light-emitting elements ED1a, ED1b, ED1c can be connected in parallel.

The display apparatus according to various embodiments of the present disclosure can be described as follows.

A display apparatus according to embodiments of the present disclosure can include a substrate including a display area and a non-display area, at least two emission areas disposed on the display area and constituting one sub-pixel, a trench portion disposed at least outside each emission area, at least two contact areas disposed to be spaced apart from the respective emission areas, a first electrode disposed in each emission area, a contact wiring portion disposed in each contact area, an emission layer disposed on the first electrode, and a second electrode disposed on the emission layer and separated in the two emission areas by the trench portion, where the separated portions of the second electrode can be electrically connected to the contact wiring portions, respectively.

While the embodiments of the present disclosure have been described in detail with reference to the accompanying drawings, it should be understood by a person skilled in the art that the present disclosure is not necessarily limited to the above embodiments, and the above embodiments can be practiced in various modified forms without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for the purpose of limiting the disclosure.

What is claimed is:

1. A display apparatus comprising:
a substrate including a display area and a non-display area;
at least two emission areas disposed on the display area and constituting one sub-pixel;
a trench portion disposed at least outside of each of the at least two emission areas;
at least two contact areas disposed to be spaced apart from the respective emission areas;
a first electrode disposed in each of the at least two emission areas;
contact wiring portions disposed in the at least two contact areas;
an emission layer disposed on the first electrode; and
a second electrode disposed on the emission layer and separated in the at least two emission areas by the trench portion,
wherein separated portions of the second electrode are electrically connected to the contact wiring portions, respectively.

2. The display apparatus of claim 1, wherein the at least two emission areas include a first-first sub-pixel and a first-second sub-pixel both configured to emit light of a same color.

3. The display apparatus of claim 1, wherein portions of surfaces of the contact wiring portions are exposed, and the separated portions of the second electrode contact the entire surfaces of the exposed portions of the contact wiring portions, respectively.

4. The display apparatus of claim 2, wherein the substrate further includes:
a transistor;
a planarization layer covering the transistor; and
a connection electrode disposed on the planarization layer and electrically connected to the transistor, and
wherein the first-first sub-pixel and the first-second sub-pixel are electrically connected to the transistor through the connection electrode.

5. The display apparatus of claim 4, further comprising a protective layer disposed on the planarization layer,
wherein the trench portion includes a bottom surface recessed in a thickness direction of the protective layer, and opposite sidewalls extending from the bottom surface, and
wherein the protective layer includes an inorganic insulating material.

6. The display apparatus of claim 4, further comprising a step difference planarization layer disposed on the planarization layer,
wherein the trench portion includes a bottom surface recessed in a thickness direction of the step difference planarization layer, and opposite sidewalls extending from the bottom surface, and
wherein the step difference planarization layer exposes a portion of a surface of the connection electrode.

7. The display apparatus of claim 1, wherein the display apparatus includes a plurality of emission areas arranged in a plurality of row directions and a plurality of column directions on the substrate, the plurality of emission areas including the at least two emission areas constituting the one sub-pixel,
wherein emission areas configured to emit light of different colors are disposed alternately in the plurality of row directions and the plurality of column directions, and
wherein the at least two emission areas constituting the one sub-pixel are disposed in one column direction.

8. The display apparatus of claim 1, wherein the display area includes a plurality of transmission areas and a plurality of pixel areas,
wherein each of the plurality of pixel areas includes a plurality of emission areas, and each of the plurality of transmission areas does not overlap with one of the plurality of emission areas.

9. The display apparatus of claim 1, further comprising a bank disposed in the at least two emission areas and the at least two contact areas, covering edges of each of the at least two emission areas and the at least two contact areas, and having an end protruding further than a sidewall of the trench portion.

10. The display apparatus of claim 1, further comprising a structure disposed within the trench portion,
wherein the structure includes:
a lower pattern including the emission layer; and
an upper pattern disposed on the lower pattern and including the second electrode.

11. The display apparatus of claim 6, further comprising a plurality of protrusion patterns disposed on a same plane as the first electrode and the contact wiring portions, and having an end protruding further than at least one of the sidewalls of the trench portion.

12. The display apparatus of claim 11, further comprising a bank disposed in the at least two emission areas and the at least two contact areas, having an end protruding further than at least one of the sidewalls of the trench portion while covering the plurality of protrusion patterns.

13. The display apparatus of claim 9, wherein the bank is disposed on a bottom surface and the sidewall of the trench portion, and includes an inorganic insulating material.

14. The display apparatus of claim 1, further comprising a structure disposed within the trench portion,
wherein the structure includes:
a lower pattern including the emission layer; and
an upper pattern including the second electrode while covering an upper surface and sidewalls of the lower pattern.

15. The display apparatus of claim 14, wherein the structure has a rectangular ring shape with a space portion disposed in an inside when viewed in a plan view.

16. The display apparatus of claim 1, wherein the second electrode is disposed in two adjacent emission areas to be separated in opposite sides with the trench portion interposed therebetween.

17. The display apparatus of claim 10, wherein the lower pattern is disposed on a bottom surface of the trench portion, without being disposed on a sidewall of the trench portion.

18. The display apparatus of claim 14, wherein the lower pattern is disposed on a bottom surface of the trench portion, without being disposed on a sidewall of the trench portion.
